(19) United States
(12) Patent Application Publication
(10) Pub. No.: US 2018/0006219 A1
(43) Pub. Date: Jan. 4, 2018

(54) METHODS OF MANUFACTURING SEMICONDUCTOR DEVICES

(71) Applicant: Samsung Electronics Co., Ltd., Suwon-si (KR)

(72) Inventors: Jae-Hun SEO, Suwon-si (KR); Jung-Ik OH, Hwaseong-si (KR); Yoo-Chul KONG, Seoul (KR); Woo-Ram KIM, Seoul (KR); Jong-Chul PARK, Seongnam-si (KR); Gwang-Hyun BAEK, Seoul (KR); Bok-Yeon WON, Yongin-si (KR); Hye-Jin CHOI, Bucheon-si (KR)

(21) Appl. No.: 15/414,911

(22) Filed: Jan. 25, 2017

(30) Foreign Application Priority Data
Jul. 1, 2016 (KR) 10-2016-0083574

(51) Int. Cl. H01L 45/00; H01L 27/24; H01L 43/12; H01L 27/22; H01L 43/08; H01L 43/02; H01L 43/10

(52) U.S. Cl. CPC H01L 45/1675; H01L 27/2463; H01L 45/06; H01L 45/144; H01L 45/1233; H01L 45/1253; H01L 43/12; H01L 43/10; H01L 43/08; H01L 43/02; H01L 45/08; H01L 45/142; H01L 45/143; H01L 27/222; H01L 45/147; H01L 45/146

(57) ABSTRACT

In method of manufacturing a semiconductor memory device, a selection layer and a variable resistance layer may be sequentially formed on a substrate. A preliminary first mask extending in a first direction may be formed on the variable resistance layer. An upper mask extending in a second direction crossing the first direction may be formed on the variable resistance layer and the preliminary first mask. The preliminary first mask may be etched using the upper mask as an etching mask to form a first mask having a pillar shape. The variable resistance layer and the selection layer may be anisotropically etched using the first mask as an etching mask to form a pattern structure including a variable resistance pattern and selection pattern sequentially stacked. The pattern structure may have a pillar shape. Damages to the pattern structure may decrease.

### CROSS-REFERENCE TO RELATED APPLICATION

This application claims priority under 35 USC §119 to Korean Patent Application No. 10-2016-0083574, filed on Jul. 1, 2016 in the Korean Intellectual Property Office (KIPO), the contents of which are herein incorporated by reference in their entirety.

### BACKGROUND

### 1. Field

Example embodiments relate to a method of manufacturing a semiconductor device. More particularly, example embodiments relate to method of manufacturing a semiconductor device including a pattern structure having a pillar shape.

### 2. Description of the Related Art

In a variable resistance memory device, memory cells may be formed at cross-points of conductive lines. Each of the memory cells may include a pattern structure having a pillar shape.

### SUMMARY

Example embodiments provide a method of manufacturing a semiconductor device including a pattern structure having a pillar shape.

According to example embodiments, there is provided a method of manufacturing a semiconductor device. In the method, a selection layer and a variable resistance layer may be sequentially formed on a substrate. A preliminary first mask may be formed on the variable resistance layer. The preliminary first mask may extend in a first direction. An upper mask may be formed on the variable resistance layer and the preliminary first mask. The upper mask may extend in a second direction crossing the first direction. The preliminary first mask may be etched using the upper mask as an etching mask to form a first mask having a pillar shape. The variable resistance layer and the selection layer may be anisotropically etched using the first mask as an etching mask to form a pattern structure including a variable resistance pattern and selection pattern sequentially stacked. The pattern structure may have a pillar shape.

According to example embodiments, there is provided a method of manufacturing a semiconductor device. In the method, a plurality of first conductive patterns may be formed on a substrate. Each of the first conductive patterns may extend in a first direction. A selection layer and a variable resistance layer sequentially formed on the first conductive patterns. A preliminary first mask may be formed on the variable resistance layer. The preliminary first mask may extend in the first direction. An upper mask may be formed on the variable resistance layer and the preliminary first mask. The upper mask may extend in a second direction crossing the first direction. The preliminary first mask may be etched using the upper mask as an etching mask to form a first mask having a pillar shape. The variable resistance layer and the selection layer may be anisotropically etched using the first mask as an etching mask to form a pattern structure including a variable resistance pattern and selection pattern sequentially stacked. The pattern structure may have a pillar shape. A plurality of second conductive patterns may be formed on the pattern structure. The first conductive patterns may extend in the second direction.

According to example embodiments, there is provided a method of manufacturing a semiconductor device that includes: forming a variable resistance layer on a substrate; forming a selection layer on the variable resistance layer; forming a preliminary first mask on the selection layer, the preliminary first mask extending in a first direction, the preliminary first mask includes a material having a high etching selectivity with respect to each of the selection layer and the variable resistance layer; forming an upper mask on the selection layer and the first mask, the upper mask extending in a second direction crossing the first direction; etching the preliminary first mask using the upper mask as an etching mask to form a first mask having a pillar shape; and anisotropically etching the variable resistance layer and selection layer using the first mask as an etching mask to form a pattern structure including a selection pattern and a variable resistance pattern sequentially stacked, the pattern structure having a pillar shape.

According to example embodiments, the selection layer and the variable resistance layer may be etched using the etching mask having the pillar shape as an etching mask to form the pattern structure including the selection pattern and the variable resistance pattern. Thus, a first etching process of the selection layer and the variable resistance layer to form structures having line shapes, forming a filling layer to fill a gap between the structures, and planarizing of the filling layer may not be performed, so that processes for forming the pattern structure may be simplified. Also, the structures having line shapes are not formed, and thus sidewalls of the structures may not be oxidized. Further, the pattern structure may be formed by etching process once the selection layer and the variable resistance layer, so that etching damages may decrease.

### BRIEF DESCRIPTION OF THE DRAWINGS

Example embodiments will be more clearly understood from the following detailed description taken in conjunction with the accompanying drawings. FIGS. 1 to 29 represent non-limiting, example embodiments as described herein.

FIGS. 1 to 20 are cross-sectional views and plan views illustrating stages of a method of manufacturing a pattern structure of a semiconductor device in accordance with example embodiments;

FIGS. 21 to 27 are cross-sectional views illustrating stages of a method of manufacturing a semiconductor device in accordance with example embodiments; and

FIGS. 28 and 29 are cross-sectional views illustrating stages of a method of manufacturing a semiconductor device in accordance with example embodiments.

### DESCRIPTION OF EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

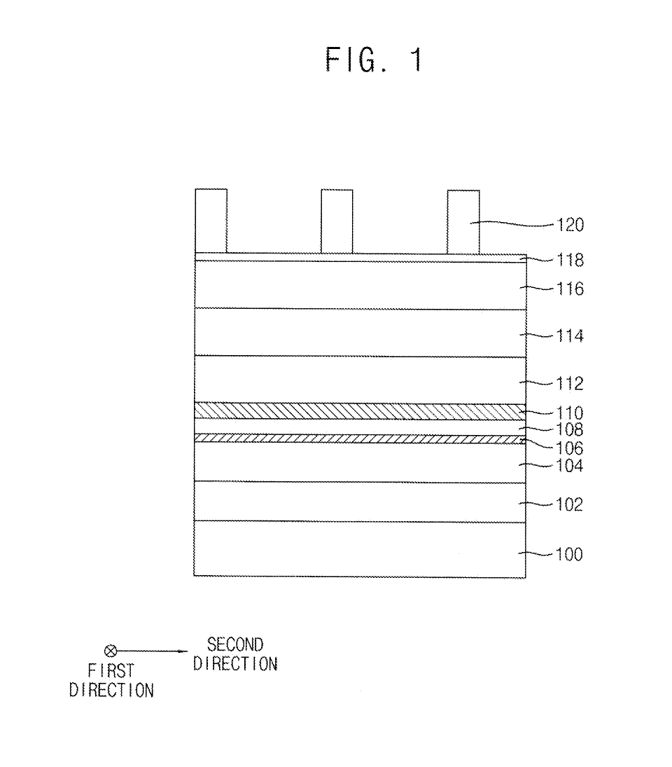

FIGS. 1 to 20 are cross-sectional views and plan views illustrating stages of a method of manufacturing a pattern structure of a semiconductor device in accordance with example embodiments.

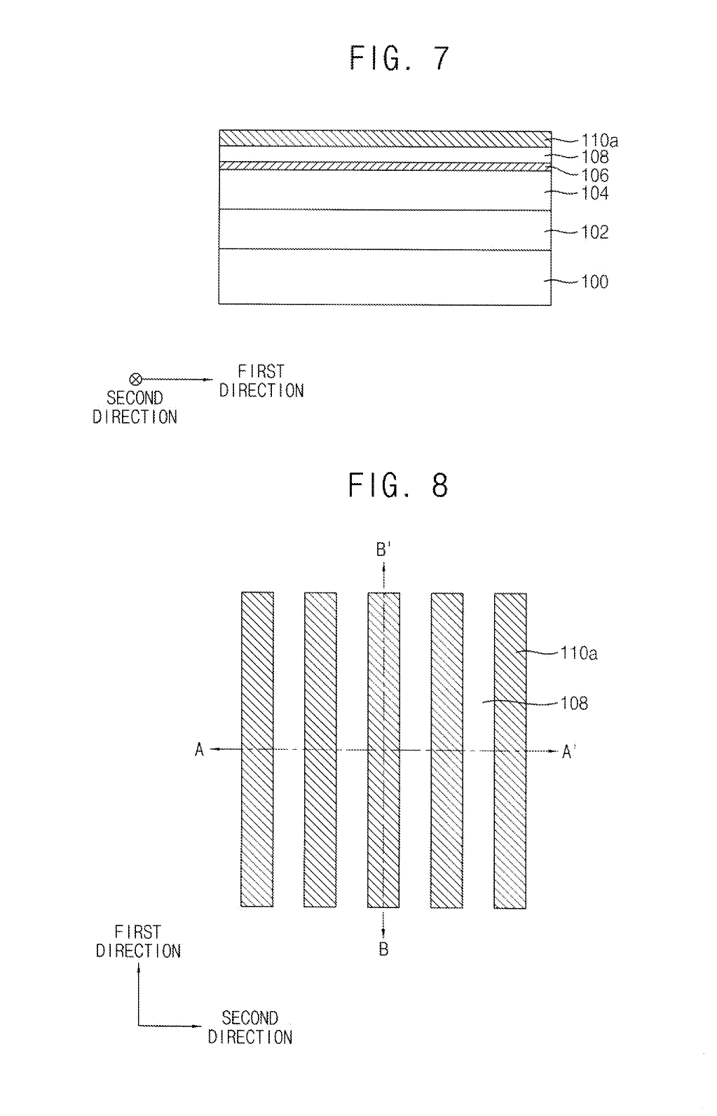

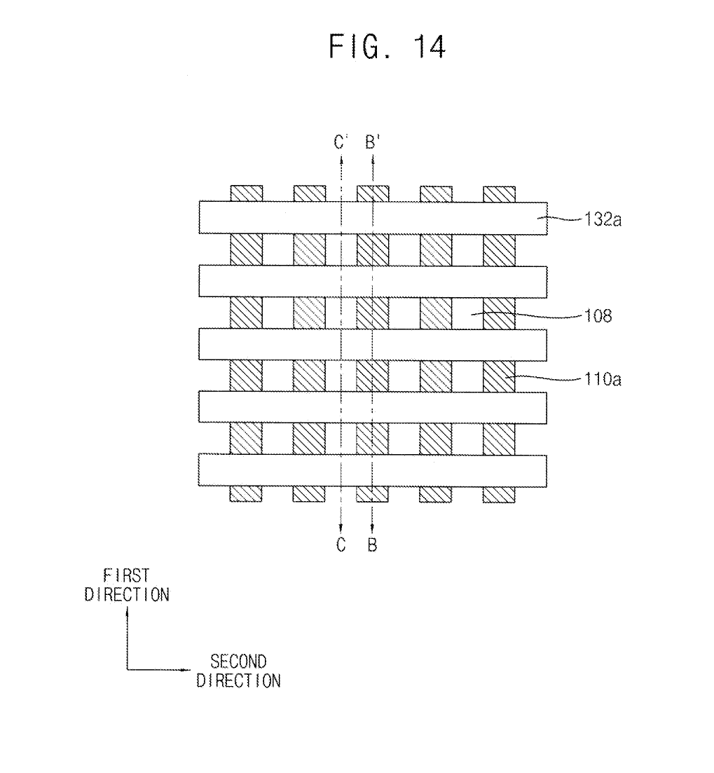

Particularly, FIGS. 8, 14, 17 and 20 are plan views. FIGS. 1, 2, 3, 4, 5, 6, 7, 9 and 10 are cross-sectional views taken along a line A-A′ indicated in FIG. 8, FIGS. 7, 11, 12, 15 and 18 are cross-sectional views taken along a line B-B′ indicated in FIG. 8, and FIGS. 13, 16 and 19 are cross-sectional views taken along a line C-C′ indicated in FIG. 14.

Referring to FIG. 1, a selection layer 102 and a variable resistance layer 104 may be sequentially formed on a substrate 100. For example, the variable resistance layer 104 may be formed on the selection layer 102. An upper electrode layer 106, a first capping layer 108 and a first mask layer 110 may be sequentially formed on the variable resistance layer 104. A second mask layer 112, a third mask layer 114, a fourth mask layer 116 and a fifth mask layer 118 may be sequentially formed on the first mask layer 110. A first photoresist pattern 120 may be formed on the fifth mask layer 118.

In example embodiments, a conductive structure and/or an insulation pattern may be further formed on the substrate 100. In example embodiments, the selection layer 102 and the variable resistance layer 104 may be stacked in a different order. For example, the selection layer 102 may be formed on the variable resistance layer 104 and an upper electrode layer 106, a first capping layer 108 and a first mask layer 110 may be sequentially formed on the selection layer 102.

In example embodiments, the selection layer 102 and the variable resistance layer 104 may serve as etching target layers, respectively. In example embodiments, at least one material of the selection layer 102 and the variable resistance layer 104 may be the same. For example, both of the selection layer 102 and the variable resistance layer 104 may include, e.g., a chalcogenide-based material.

The selection layer 102 may serve as a switching element for selection of cells. In example embodiments, the selection layer 102 may include an ovonic threshold switch (OTS) material. A resistance of the OTS material may be variable according to a temperature thereof in an amorphous state. For example, the selection layer 102 may maintain the amorphous state in a range of temperature greater than the variable resistance layer 104. In the amorphous state, the resistance of the OTS material may be greatly varied according to the temperature.

The OTS material may include germanium (Ge), silicon (Si), arsenic (As) and/or tellurium (Te). Also, the OTS material may further include selenium (Se) and/or sulfur (S).

The OTS material may include, e.g., AsTeGeSiIn, GeTe, SnTe, GeSe, SnSe, AsTeGeSiSbS, AsTeGeSiIP, AsTeGeSi, As2Te3Ge, As2Se3Ge, As25(Te90Ge10)75, Te40As35Si18Ge6.75In0.25, Te28As34.5Ge15.5S22, Te39As36 Si17Ge7P, As10Te21S2Ge15Se50Sb2, Si5Te34As28Ge11S21Se1, AsTeGeSiSeNS, AsTeGeSiP, AsSe, AsGeSe, AsTeGeSe, ZnTe, GeTePb, GeSeTe, AlAsTe, SeAsGeC, SeTeGeSi, GeSbTeSe, GeBiTeSe, GeAsSbSe, GeAsBiTe, GeAsBiSe, GexSel-x, etc.

In some embodiments, the selection layer 102 may include, e.g., polysilicon, so that the selection layer 102 may be formed into a diode.

In example embodiments, the variable resistance layer 104 may include a material of which a resistance may be changed by a phase change or a phase transition. The variable resistance layer 104 may include a chalcogenide-based material in which germanium (Ge), antimony (Sb) and/or tellurium (Te) are combined by a given ratio. In this exemplary embodiment, the selection layer 102 and the variable resistance layer 104 may include Ge—Sb—Te.

In some example embodiments, the variable resistance layer 104 may include a material of which a resistance may be changed by a magnetic field or a spin transfer torque (STT). The variable resistance layer may include a ferromagnetic material, e.g., iron (Fe), nickel (Ni), cobalt (Co), dysprosium (Dy), gadolinium (Gd), etc.

In some example embodiments, the variable resistance layer 104 may include, e.g., a transition metal oxide or a perovskite-based material.

In example embodiments, a middle conductive layer may be further formed between the selection layer 102 and the variable resistance layer 104.

That is, the selection layer 102 may include the OTS material and the variable resistance layer 104 may include Ge—Sb—Te. The selection layer 102 and the variable resistance layer 104 may include similar elements, and thus etching characteristics of the selection layer 102 and the variable resistance layer 104 may be substantially the same as or similar to each other. The selection layer 102 and the variable resistance layer 104 may be easily etched by the same etching process subsequently performed.

The upper electrode layer 106 may include a metal nitride or a metal silicon nitride. In example embodiments, the upper electrode layer 106 may include, e.g., titanium nitride (TiNx), titanium silicon nitride (TiSiNx), tungsten nitride (WNx), tungsten silicon nitride (WSiNx), tantalum nitride (TaNx), tantalum silicon nitride (TaSiNx), zirconium nitride (ZrNx), zirconium silicon nitride (ZrSiNx), titanium aluminum nitride, etc.

The first capping layer 108 may include an insulation material, e.g., silicon nitride.

The first mask layer 110 may serve as an etching mask for etching the selection layer 102 and the variable resistance layer 104. Thus, the first mask layer 110 may include a material having a high etching selectivity with respect to each of the selection layer 102, the variable resistance layer 104 and the upper electrode layer 106.

In example embodiments, an etching selectivity between each of the selection layer 102, the variable resistance layer 104 and the upper electrode layer 106, and the first mask layer 110 may be equal to or more than about 10:1. For example, an etch rate of the first mask layer 110 may be less than about 1/10 of an etch rate of each of the variable resistance layer 104 and the selection layer 102 during anisotropically etching the variable resistance layer 104 and the selection layer 102. Also, an etch rate of the first mask layer 110 may be less than about 1/10 of an etch rate of the upper electrode layer 106. As the etching selectivity between each of the selection layer 102, the variable resistance layer 104 and the upper electrode layer 106, and the first mask layer 110 is higher, the first mask layer 110 may have a relatively thinner thickness. In example embodiments, the first mask layer 110 may have a thickness less than about ⅕ of a sum of thicknesses of the selection layer 102 and the variable resistance layer 104, but the disclosure is not limited thereto.

In example embodiments, the first mask layer 110 may include an insulation material, e.g., a metal oxide, a metal nitride, carbon, etc. The first mask layer 110 may include, e.g., aluminum oxide, aluminum nitride, hafnium oxide, diamond-like carbon (DCL), etc.

In example embodiments, the first mask layer 110 may have a thickness of less than about 100 Å. Preferably, the first mask layer 110 may have a thickness in range of about 20 Å to 100 Å. When the first mask layer 110 has a thickness of less than about 100 Å, a subsequent planarization process for a seventh mask layer may not be performed. However, the thickness of the first mask layer 110 may not be limited to the above value.

The second to fifth mask layers 112, 114, 116 and 118 may serve as masks for patterning the first mask layer 110 in a first direction. As a plurality of mask layers, e.g., the second to fifth mask layers 112, 114, 116 and 118 are formed, the first mask layer 110 may be patterned to have a fine width. However, in some example embodiments, at least one of the second to fifth mask layers 112, 114, 116 and 118 may not be formed.

In example embodiments, the second mask layer 112 may include silicon oxide. In example embodiments, the third mask layer 114 may include polysilicon. In example embodiments, the fourth mask layer 116 may include a spin on hardmask (SOH) layer. The spin on hard mask layer may include carbon. In example embodiments, the fifth mask layer 118 may include, e.g., silicon oxynitride, silicon nitride, etc.

In example embodiments, the second, third and fifth mask layers 112, 114 and 118 may be formed by, e.g., a chemical vapor deposition (CVD) process, an atomic layer deposition (ALD) process, etc. The fourth mask layer 116 may be formed by, e.g., a spin coating process.

In example embodiments, a bottom anti-reflective coating (BARC) layer may be further formed on the fifth mask layer 118.

The first photoresist pattern 120 may be formed by a photo process. The first photoresist pattern 120 may extend in the first direction, and a plurality of first photoresist patterns 120 may be formed in a second direction substantially perpendicular to the first direction. In example embodiments, a width in the second direction of the first photoresist pattern 120 may be substantially the same as a distance between preliminary first masks 110a (refer to FIG. 6) subsequently formed. A distance between the first photoresist patterns 120 may be substantially the same as a sum of a distance between the preliminary first masks 110a and twice a width in the second direction of the preliminary first mask 110a.

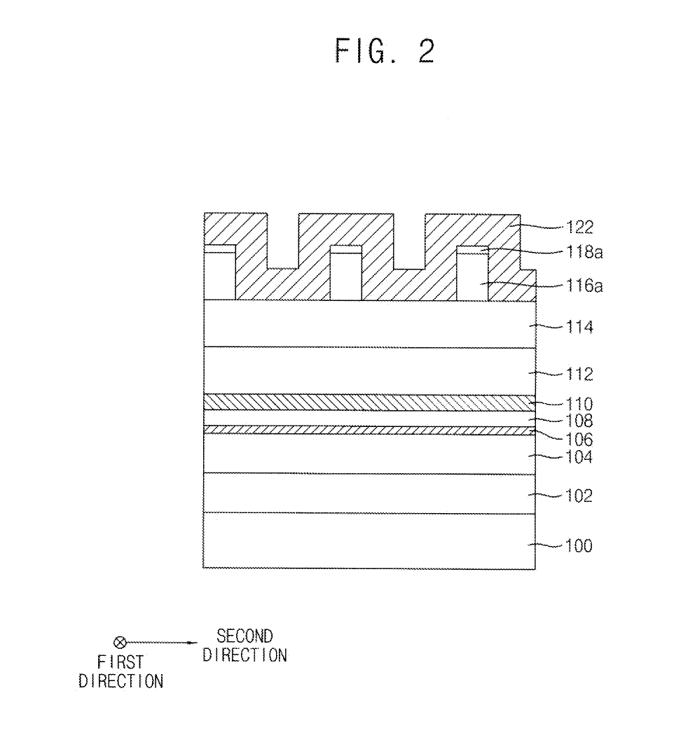

Referring to FIG. 2, the fifth mask layer 118 and the fourth mask layer 116 may be sequentially etched using the first photoresist pattern 120 as an etching mask to form a fifth mask 118a and a fourth mask 116a, respectively. During the etching process, the first photoresist pattern 120 may be mostly removed.

A sixth mask layer 122 may be formed on surfaces of the third mask layer 114 and a first structure including the fourth mask 116a and the fifth mask 118a sequentially stacked. The sixth mask layer 122 may be formed to have a thickness substantially the same as a width in the second direction of the preliminary first mask 110a. In example embodiments, the sixth mask layer 122 may be formed by a CVD process, an ALD process, etc. The sixth mask layer 122 may include a material having a high etching selectivity with respect to the third mask layer 114. In example embodiments, the sixth mask layer 122 may include, e.g., silicon oxide.

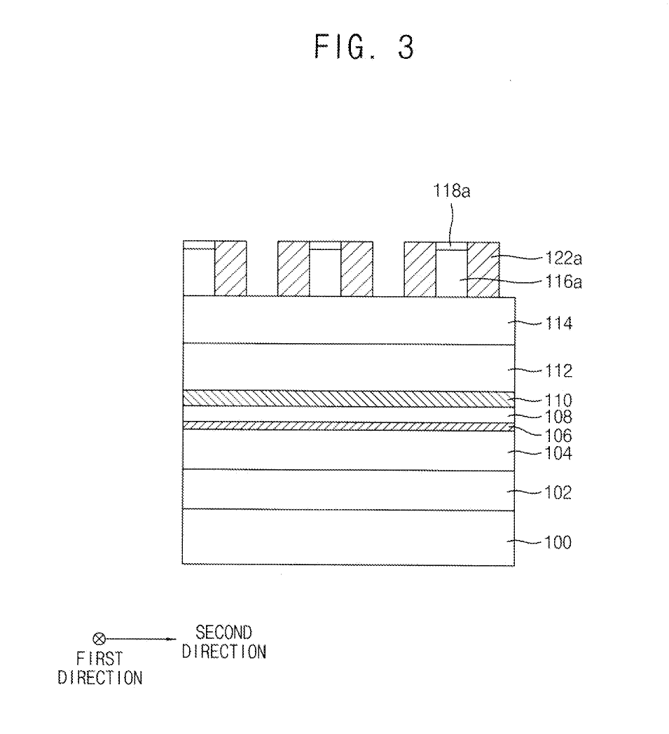

Referring to FIG. 3, the sixth mask layer 122 may be anisotropically etched to form a sixth mask 122a on a sidewall of the first structure. The sixth mask 122 may extend in the first direction. The sixth mask 122a may have a thickness substantially the same as a width in the second direction of each of the preliminary first masks 110a, and may have the thickness substantially the same as a distance between the preliminary first masks 110a. In example embodiments, during the etching process for the sixth mask layer 122, the fifth mask 118a may be mostly or partially removed.

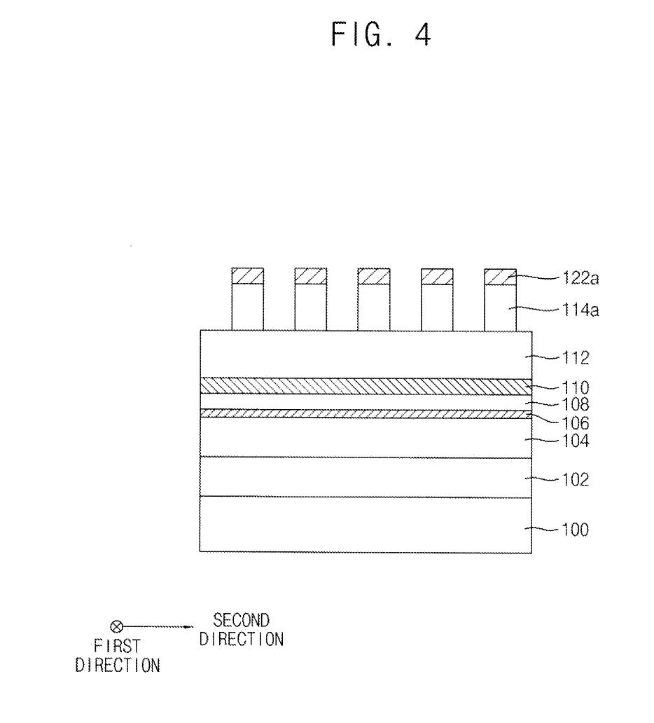

Referring to FIG. 4, the first structure may be removed. The third mask layer 114 may be anisotropically etched using the sixth mask 122a as an etching mask to form a third mask 114a.

During the etching process for the third mask layer 114, an upper surface of the sixth mask 122a may be partially removed, so that a height of the sixth mask 122a may be decreased. Alternatively, during the etching process for the third mask layer 114, the sixth mask 122a may be completely removed.

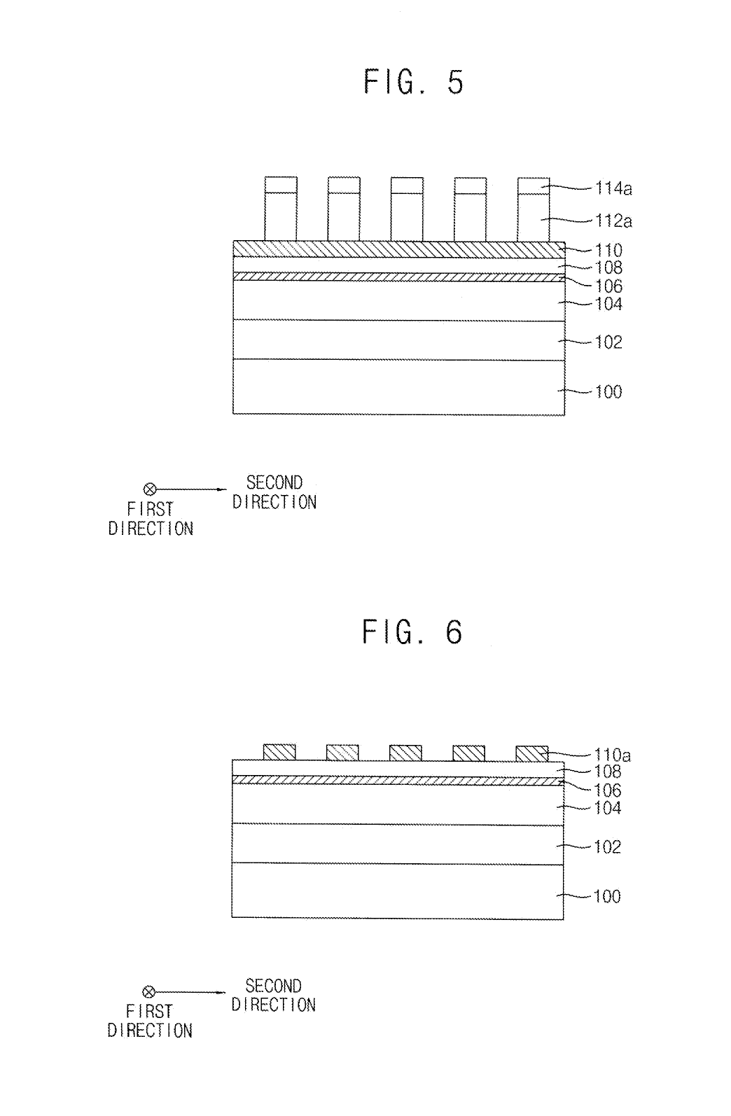

Referring to FIG. 5, the second mask layer 112 may be anisotropically etched using a second structure including the third mask 114a and the sixth mask 122a sequentially stacked as an etching mask to form a second mask 112a.

In example embodiments, during the etching process, the sixth mask 122a may be completely removed and the third mask 114a may be partially etched. Thus, a height of the third mask 114a may be decreased. Alternatively, during the etching process, the third mask 114a and the sixth mask 122a may be completely removed.

FIGS. 6, 7 and 8 illustrate the preliminary first mask 110a. FIG. 6 is a cross-sectional view taken along a line in the first direction, and FIG. 7 is a cross-sectional view taken along a line in the second direction. FIG. 8 is a plan view of the preliminary first mask 110a.

Referring to FIGS. 6 to 8, the first mask layer 110 may be etched using the second mask 112a as an etching mask to form the plurality of preliminary first masks 110a. An upper surface of the first capping layer 108 may be exposed by a gap between the preliminary first masks 110a.

In example embodiments, during the etching process for the first mask layer 110, the third mask 114a may be completely removed. Also, the second mask 112a may be removed by, e.g., an isotropic etching process.

Each of the preliminary first masks 110a may extend in the first direction, and the preliminary first masks 110a may be arranged in the second direction.

As described above, the preliminary first mask 110a may be formed on the first capping layer 108 by a first double patterning process.

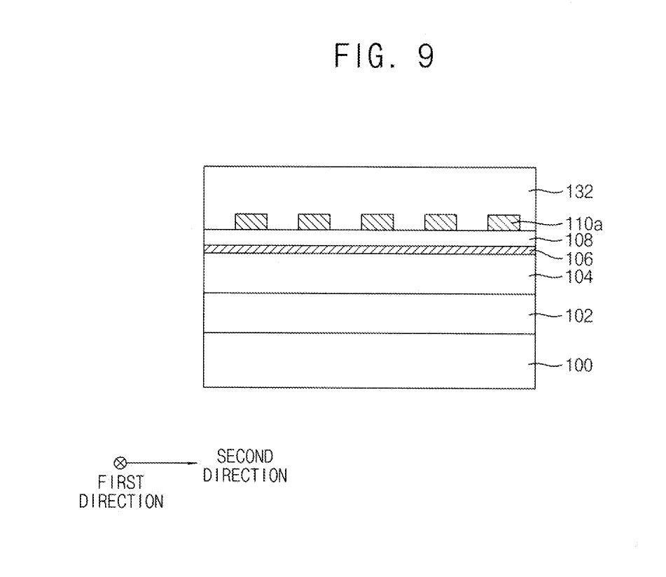

Referring to FIG. 9, a seventh mask layer 132 may be formed on the preliminary first mask 110a and the first capping layer 108.

The seventh mask layer 132 may serve as an etching mask for etching the preliminary first mask 110a. In example embodiments, the seventh mask layer 132 may include a material that may be removed in an etching process for the selection layer 102 and the variable resistance layer 104.

In example embodiments, the seventh mask layer 132 may include a material substantially the same as a material of the second mask layer 112. The seventh mask layer 132 may include, e.g., silicon oxide.

In this exemplary embodiment, a height of a first upper surface of the seventh mask layer 132 on the preliminary first mask 110a may be different from a height of a second upper surface of the seventh mask layer 132 on the first capping layer 108. However, as a height of the preliminary first mask 110a decreases, a height difference between the first and second upper surfaces of the seventh mask layer 132 may decrease. In example embodiments, when the height of the preliminary first mask 110a is less than about 100 Å, the seventh mask layer 132 may be formed to have a substantially flat upper surface without performing a planarization process. Thus, in example embodiments, the planarization process for the seventh mask layer 132 may not be performed. Alternatively, the planarization process for the seventh mask layer 132 may be performed.

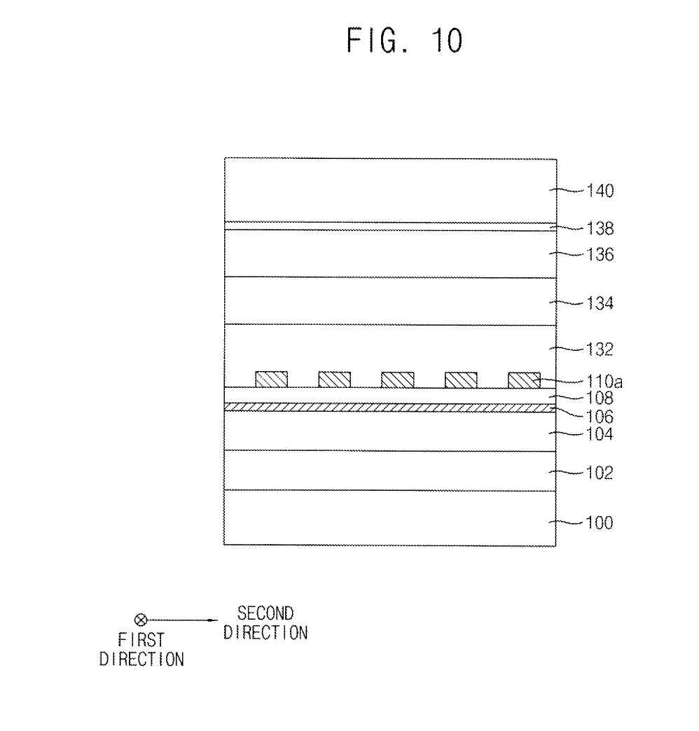

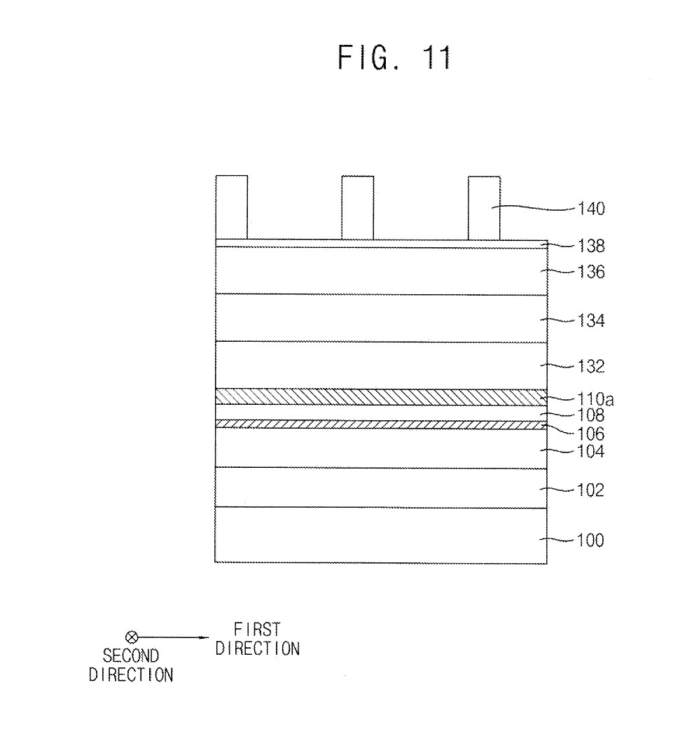

FIG. 10 is a cross-sectional view taken along a line in the first direction, and FIG. 11 is a cross-sectional view taken along a line in the second direction according to exemplary embodiments.

Referring to FIGS. 10 and 11, an eighth mask layer 134, a ninth mask layer 136 and a tenth mask layer 138 may be sequentially formed on the seventh mask layer 132. A second photoresist pattern 140 may be formed on the tenth mask layer 138.

The eighth, the ninth and the tenth mask layers 134, 136 and 138 may include materials substantially the same as those of the third, the fourth and the fifth mask layers 114, 116 and 118, respectively. Thus, processes for forming the eighth, the ninth and the tenth mask layers 134, 136 and 138 may be substantially the same as or similar to processes for forming the third, the fourth and the fifth mask layers 114, 116 and 118, respectively, as illustrated with reference to FIG. 1.

The second photoresist pattern 140 may be formed by a photo process. The second photoresist pattern 140 may extend in the second direction, and a plurality of second photoresist patterns 140 may be formed in the first direction. That is, the second photoresist pattern 140 and the preliminary first mask 110a may be disposed to cross each other.

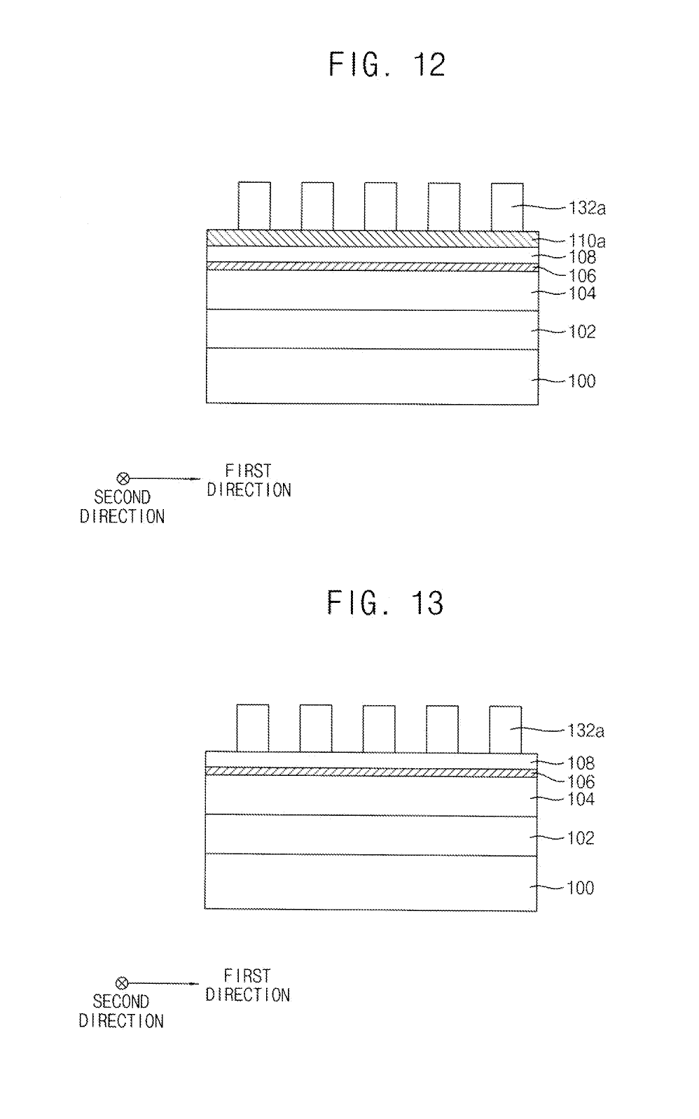

FIG. 14 is a plan view illustrating a preliminary first mask and a seventh mask according to exemplary embodiments. FIGS. 12 and 13 are cross-sectional views taken along lines B-B′ and C-C′, respectively, in FIG. 14.

Referring to FIGS. 12, 13 and 14, processes substantially the same as or similar to those illustrated with reference to FIGS. 2 to 5 may be performed. Thus, a seventh mask 132a may be formed on the preliminary first mask 110a. The seventh mask 132a may be formed by a second double patterning process. As the second photoresist pattern 140 extends in the second direction, the seventh mask 132a may extend in the second direction.

The seventh mask 132a and the preliminary first mask 110a may be disposed to cross each other. A portion of a lower surface of the seventh mask 132a may contact the preliminary first mask 110, and other portions of the lower surface of the seventh mask 132a may contact the first capping layer 108. In example embodiments, a portion of the eighth mask may remain on the seventh mask 132a.

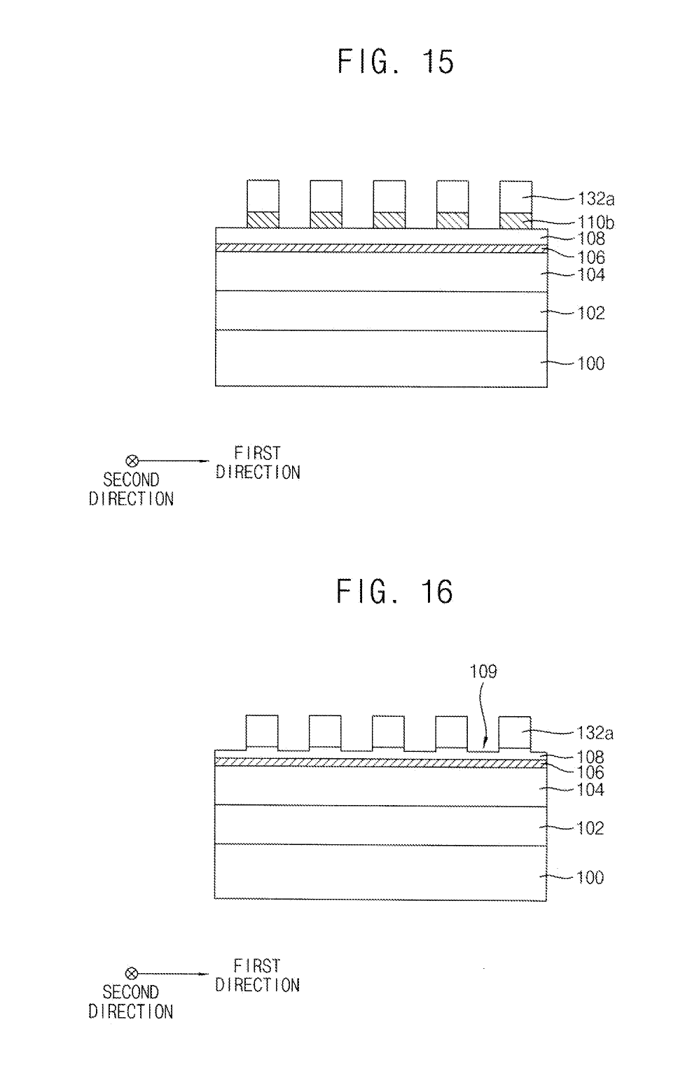

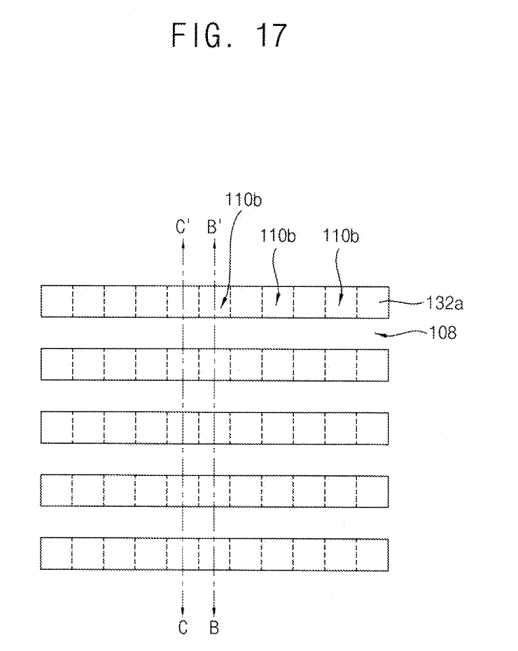

FIG. 17 is a plan view illustrating an eighth mask and a first mask according to exemplary embodiments. FIGS. 15 and 16 are cross-sectional views taken along lines B-B′ and C-C′, respectively, in FIG. 17.

Referring to FIGS. 15, 16 and 17, the preliminary first mask 110a may be etched using the seventh mask 132a as an etching mask to form the first mask 110b. The first mask 110b may be formed by etching the preliminary first layer 110 in each of the first and second directions. Thus, the first mask 110b may have a pillar shape as viewed from a cross-section, and a plurality of first masks 110b may be regularly formed in the first and second directions.

During etching the preliminary first mask 110a, the seventh mask 132a may be partially or completely removed. In example embodiments, the seventh mask 132a extending in the second direction may remain on the first mask 110b and the first capping layer 108.

Before the etching process, the seventh mask 132a and the first capping layer 108 may be alternately disposed between the preliminary first masks 110a. Thus, when the etching process is performed, an upper surface of the capping layer may be partially etched to form a recess therein, as shown in FIG. 16.

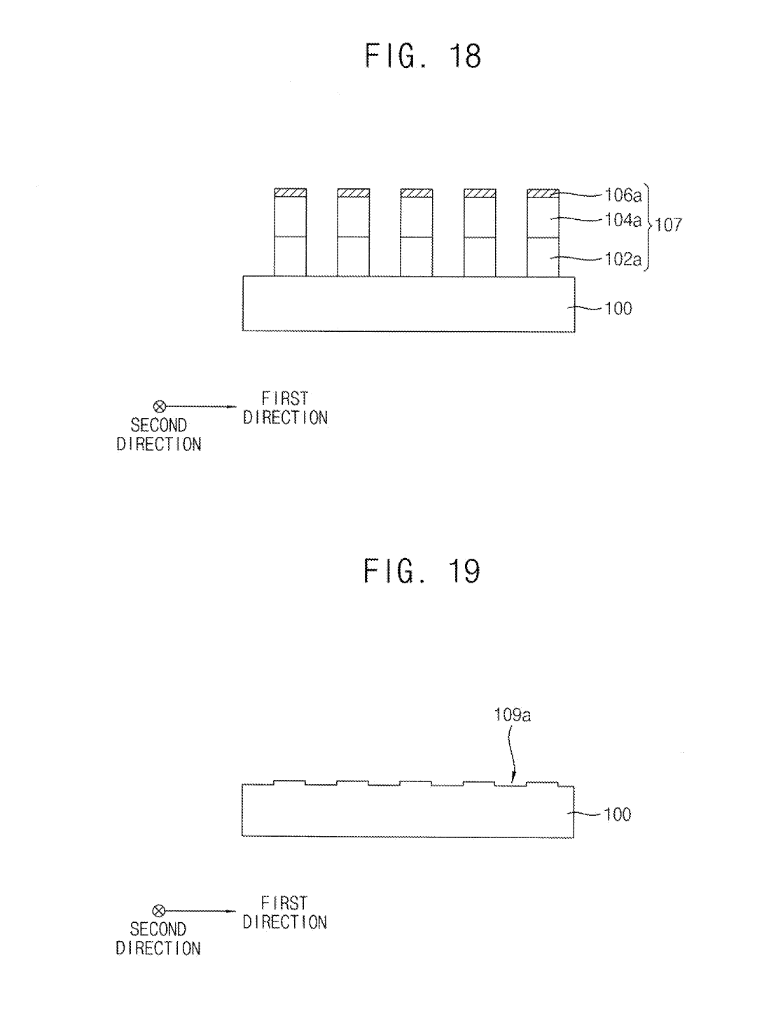

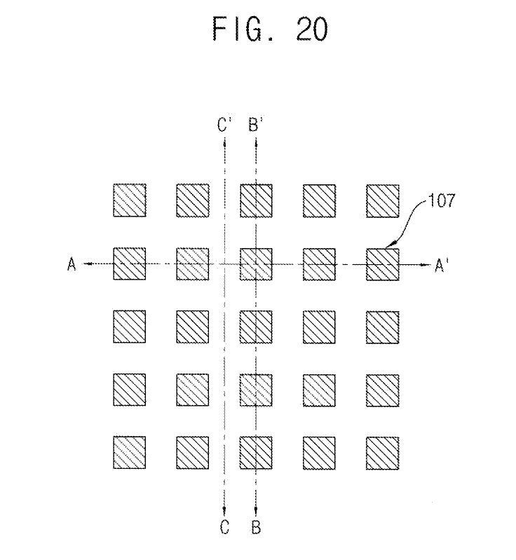

FIG. 20 is a plan view illustrating a pattern structure according to exemplary embodiments. FIGS. 18 and 19 are cross-sectional views taken along lines B-B′ and C-C′, respectively, in FIG. 20.

Referring to FIGS. 18, 19 and 20, the seventh mask 132a may be removed by an etching process. The first capping layer 108, the upper electrode layer 106, the variable resistance layer 104 and the selection layer 102 may be sequentially and anisotropically etched using the first mask 110b as an etching mask. In example embodiments, during the etching process, the first capping layer 108 may be partially or completely removed.

In example embodiments, the seventh mask 132a, the first capping layer 108, the upper electrode layer 106, the variable resistance layer 104 and the selection layer 102 may be etched by performing an etching process under substantially the same process condition.

In example embodiments, both of the variable resistance layer 104 and the selection layer 102 may include a chalcogenide-based material. Thus, etch rates of the variable resistance layer 104 and the selection layer 102 may be substantially the same as or similar to each other. Also, the seventh mask 132a may be etched with an etch rate substantially the same as or similar to the etch rates of the variable resistance layer 104 and the selection layer 102, in the etching process.

In example embodiments, the first mask 110b may have an etch rate less than about 1/10 of the etch rates of the variable resistance layer 104 and the selection layer 102, in the etching process, but the disclosure is not limited thereto.

Thus, a pattern structure 107 including a selection pattern 102a, a variable resistance pattern 104a and an upper electrode 106a sequentially stacked may be formed on the substrate 100. A plurality of pattern structures 107 may be formed in each of the first and second directions.

Before the etching process for forming the pattern structure 107, the recess may be disposed on the first capping layer 108 between the seventh masks 132a. Thus, when the etching process is performed, the recess 109 on the first capping layer 108 may be transferred onto an upper surface of the substrate 100 so that a recess 109a may be formed on the substrate 100 between the pattern structures 107, as shown in FIG. 19. The recess 109a may be formed at a region in which the seventh mask 132a and the preliminary first mask 110a are not formed.

In example embodiments, the pattern structure 107 may be formed by a first etching process for the first capping layer 108, the upper electrode layer 106, the variable resistance layer 104 and the selection layer 102 using the first mask 110b having a pillar shape as an etching mask. Thus, during the first etching process, the oxidation of sidewalls of the pattern structure 107 and etching damages to the pattern structure 107 may decrease.

In general, the first capping layer, the upper electrode layer, the variable resistance layer and the selection layer may be etched in the first direction to form a space. A filling layer including an insulation material may be formed to fill the space, and an upper portion of the filling layer may be planarized. Then, the first capping layer, the upper electrode layer, the variable resistance layer, the selection layer and the filling layer may be etched in the second direction to form a pattern structure. For example, the pattern structure may be formed by performing the etching process twice, depositing the filling layer, and planarizing the filling layer. Also, in the second etching process, the first capping layer, the upper electrode layer, the variable resistance layer, the selection layer and the filling layer may be etched altogether, and thus the second etching process may be difficult.

However, in example embodiments, depositing the filling layer and planarizing the filling layer may not be performed, so that the process may be simplified. Also, as the filling layer may not be etched, the first capping layer, the upper electrode layer, the variable resistance layer, and the selection layer may be easily etched.

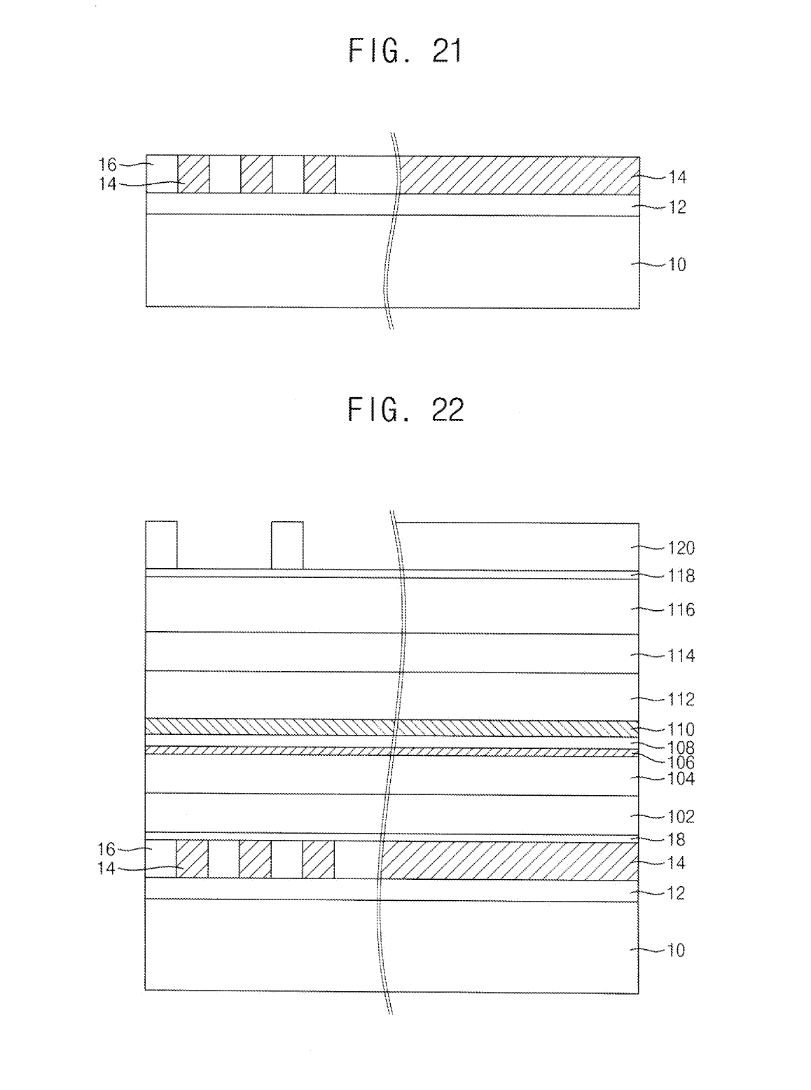

FIGS. 21 to 27 are cross-sectional views illustrating stages of a method of manufacturing a semiconductor device in accordance with example embodiments.

Particularly, each of FIGS. 21 to 25 and 27 includes a cross-sectional view of the pattern structure taken along a line in the second direction, which is a left portion, and a cross-sectional view of the pattern structure taken along a line in the first direction, which is a right portion. FIG. 26 includes a cross-sectional view of a portion between the pattern structures taken along a line in the second direction, which is a left portion, and a cross-sectional view of the portion between the pattern structures taken along a line in the first direction, which is a right portion. The pattern structure may be formed by performing processes substantially the same as or similar to processes illustrated with reference to FIGS. 1 to 20.

Referring to FIG. 21, first conductive patterns 14 each extending in the first direction may be formed on the substrate 10. The first conductive patterns 14 may be formed in the second direction. A first insulation pattern 16 may be formed to fill a gap between the first conductive patterns 14.

In example embodiments, lower elements, e.g., transistors may be formed on a substrate 10, and an insulation layer 12 may be formed to cover the lower elements. The first conductive pattern 14 may be formed on the insulation layer 12.

In example embodiments, the first conductive pattern 14 may be formed by performing a photolithograph process. Particularly, a first conductive layer may be formed on the substrate 10. The first conductive layer may include, e.g., a metal or a metal nitride. In example embodiments, the first conductive layer may be formed to include a first barrier layer, a first conductive layer and a second barrier layer sequentially stacked. A hard mask may be formed on the first conductive layer, and the first conductive layer may be etched using the hard mask as an etching mask to form the first conductive pattern 14 extending in the first direction. An insulation layer may be formed to fill a gap between a plurality of first conductive patterns 14. The insulation layer may be planarized to form the first insulation pattern 16. The hard mask may be removed.

Alternatively, the first conductive pattern 14 may be formed by a damascene process. Particularly, a first insulation layer may be formed on the substrate 10. The first insulation layer may be partially etched to form an opening extending in the first direction, so that the first insulation layer may be transformed into the first insulation pattern 16. A first conductive layer may be formed to fill the opening. The first conductive layer may be planarized until an upper surface of the first insulation pattern 16 may be exposed to form the first conductive pattern 14.

In example embodiments, the first conductive pattern 14 may serve as a word line.

Referring to FIG. 22, a lower electrode layer 18 may be formed on the first conductive pattern 14 and the first insulation pattern 16. The lower electrode layer 18 may include, e.g., titanium nitride (TiNx), titanium silicon nitride (TiSiNx), tungsten nitride (WNx), tungsten silicon nitride (WSiNx), tantalum nitride (TaNx), tantalum silicon nitride (TaSiNx), zirconium nitride (ZrNx), zirconium silicon nitride (ZrSiNx), titanium aluminum nitride, etc.

The selection layer 102 and the variable resistance layer 104 may be sequentially formed on the lower electrode layer 18. The upper electrode layer 106, the first capping layer 108 and the first mask layer 110 may be sequentially formed on the variable resistance layer 104. In other example embodiments, the variable resistance layer 104 and the selection layer 102 may be sequentially formed on the lower electrode layer 18 and the upper electrode layer 106, the first capping layer 108 and the first mask layer 110 may be sequentially formed on the selection layer 102. The second mask layer 112, the third mask layer 114, the fourth mask layer 116 and the fifth mask layer 118 may be sequentially formed on the first mask layer 110. The first photoresist pattern 120 extending in the first direction may be formed on the fifth mask layer 118. The processes may be substantially the same as or similar to processes illustrated with reference to FIG. 1.

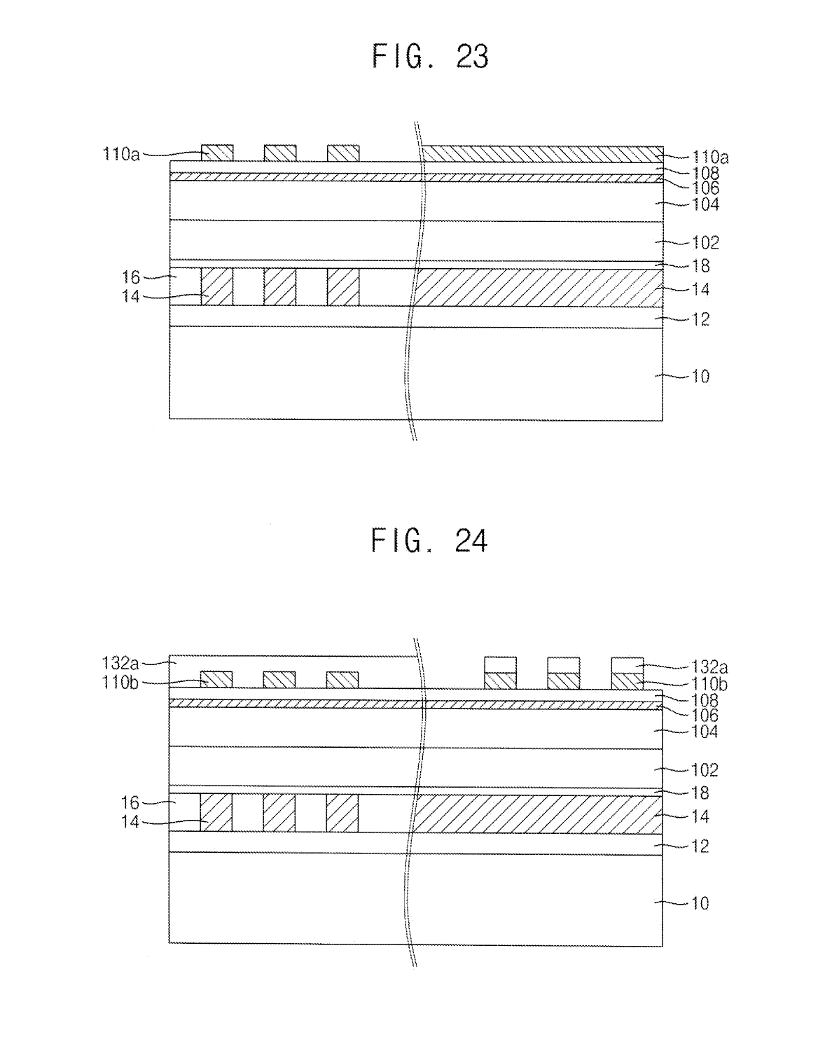

Referring to FIG. 23, processes the same as or similar to those illustrated with reference to FIGS. 2 to 8 may be performed. Thus, the preliminary first mask 110a may be formed on the first capping layer 108. The preliminary first mask 110a may extend in the first direction, and a plurality of preliminary first masks 110a may be formed in the second direction. In example embodiments, the preliminary first mask 110a may overlap the first conductive pattern 14.

Referring to FIG. 24, processes the same as or similar to those illustrated with reference to FIGS. 9 to 17 may be performed. Thus, the preliminary first mask 110a may be etched in the second direction to form the first mask 110b on the first capping layer 108. The first mask 110b may have a pillar shape. The first mask 110b may be regularly formed in each of the first and second directions. The first capping layer 108 may be exposed between the first masks 110b. An upper surface of the first capping layer 108 may include a recess, as shown in FIG. 16.

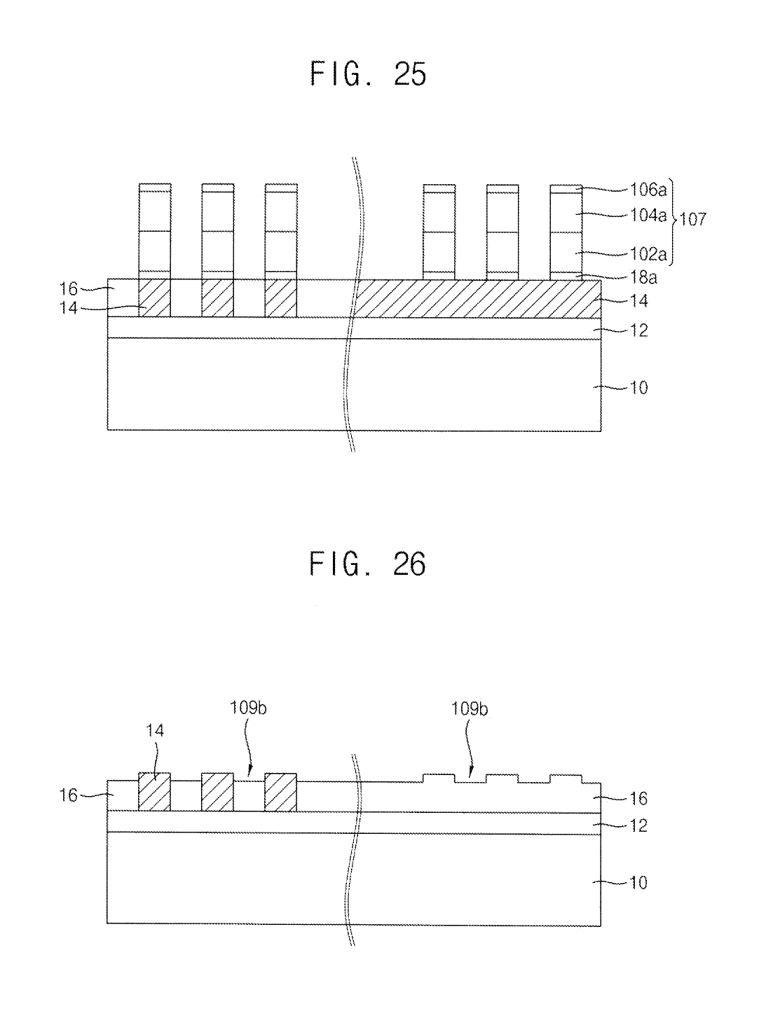

Referring to FIG. 25, the seventh mask 132a on an upper surface of the first mask 110b and the seventh mask 132a between the first masks 110b may be removed. The first capping layer 108, the upper electrode layer 106, the variable resistance layer 104 and the selection layer 102 sequentially etched using the first mask as an etching mask to form a pattern structure 107 including the selection pattern 102a, the variable resistance pattern 104a and the upper electrode 106a sequentially stacked. The processes may be substantially the same as or similar to processes illustrated with reference to FIGS. 18 and 19. The pattern structure 107 may serve as a memory cell in the semiconductor device.

The lower electrode layer 18 may be etched to form a lower electrode 18.

The pattern structure 107 may be formed on the first conductive pattern 14, and in example embodiments, a plurality of pattern structures 107 may be regularly arranged. A lower electrode 18a may be formed between the first conductive pattern 14 and the pattern structure 107.

Referring to FIG. 26, a recess 109a may be formed at an upper surface of the first insulation pattern 16 between the pattern structures 107, and the recess 109a may be transferred from the recess of the first capping layer 108.

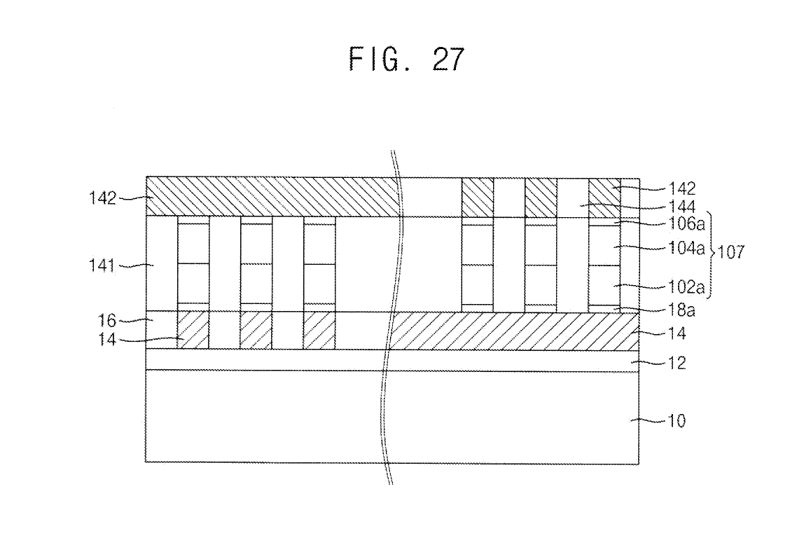

Referring to FIG. 27, the second insulation pattern 141 may be formed on the first insulation pattern 16 and the first conductive pattern 14 to fill the gap between the pattern structures 107.

In example embodiments, an insulation layer may be formed to fill the gap between the pattern structures 107, and may be planarized until an upper surface of the pattern structures 107 may be exposed. The insulation layer may include, e.g., silicon nitride, silicon oxynitride, etc.

A second conductive pattern 142 extending in the second direction may be formed on the pattern structure 107 and the second insulation pattern 141. The second conductive pattern 142 may contact the pattern structure 107. A third insulation pattern 144 may be formed to fill a gap between the second conductive patterns 142.

In example embodiments, the second conductive layer may be formed on the pattern structure 107 and the second insulation pattern 141, and a hard mask extending in the second direction may be formed on the second conductive layer. The second conductive layer may be etched using the hard mask as an etching mask to form the second conductive pattern 142. The insulation layer may be formed to fill a gap between a plurality of second conductive patterns, and may be planarized until an upper surface of the second conductive pattern may be exposed to form the third conductive pattern.

Alternatively, the second conductive pattern 142 may be formed by a damascene process. Particularly, an insulation layer may be formed on the pattern structure 107 and the second insulation pattern 141. The insulation layer may be partially etched to form a trench extending in the second direction. An upper surface of the pattern structure 107 may be exposed by the trench. A conductive layer may be formed to fill the trench, and may be planarized until an upper surface of the insulation layer to form the second conductive pattern 142. The third insulation pattern 144 may be formed between the second conductive patterns 142.

Thus, in the semiconductor device, the pattern structure 107 may be formed at a cross point of the first and second conductive patterns 14 and 142.

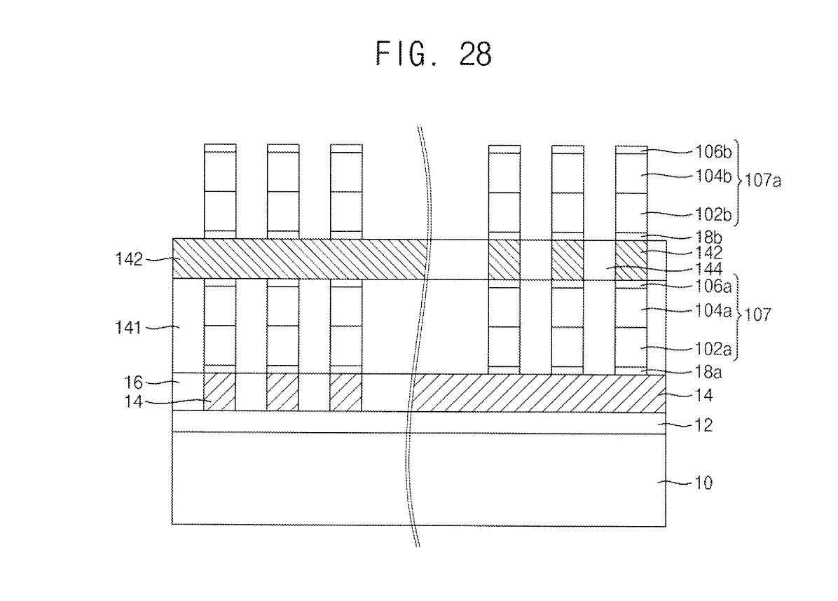

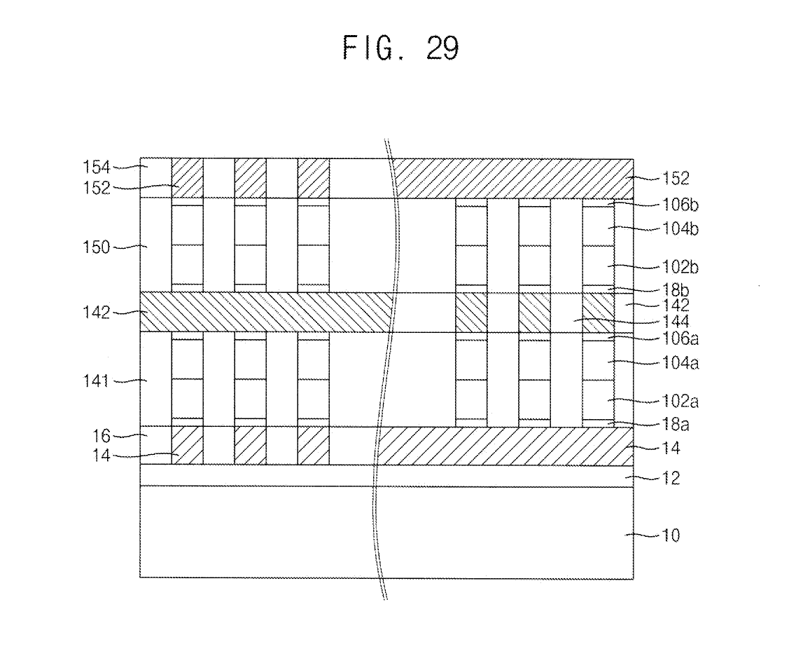

FIGS. 28 and 29 are cross-sectional views illustrating stages of a method of manufacturing a semiconductor device in accordance with example embodiments.

The semiconductor device may have a plurality of pattern structures sequentially stacked at a plurality of levels, respectively.

Processes substantially the same as or similar to processes illustrated with reference to FIGS. 21 and 27 may be performed, and additional processes may be performed to form the semiconductor device.

Referring to FIG. 28, processes substantially the same as or similar to processes illustrated with reference to FIGS. 21 and 27 may be performed.

Processes substantially the same as or similar to processes illustrated with reference to FIGS. 22 and 26 may be performed on the second conductive pattern 142 and the third insulation pattern 144. Thus, an upper pattern structure 107a may be formed on the second conductive pattern 142. The upper pattern structure 107a may be substantially the same as the pattern structure 107. The upper pattern structure 107a may overlap the pattern structure 107 in a vertical direction. A second lower electrode 18b may be formed between the second conductive pattern 142 and the upper pattern structure 107a.

The upper pattern structure 107a may serve as an upper memory cell in the semiconductor device.

Referring to FIG. 29, a fourth insulation pattern 150 may be formed on the second conductive pattern 142 and the third insulation pattern 144 to fill a gap between the upper pattern structures 107a.

A third conductive pattern 152 extending in the first direction may be formed on the fourth insulation pattern 150 and the upper pattern structure 107a. The third conductive pattern 152 may contact the upper pattern structure 107a. A fifth insulation pattern 154 may be formed between the third conductive patterns 152. In example embodiments, processes for forming the third conductive pattern 152 and the fifth insulation pattern 154 may be substantially the same as or similar to processes for forming the first conductive pattern 14 and the first insulation pattern 16, respectively, as illustrated with reference to FIG. 21.

As described above, the semiconductor device may include the pattern structures sequentially stacked in two levels. Alternatively, the semiconductor device may include the pattern structures sequentially stacked in more than two levels. The semiconductor device may be manufactured by repeatedly performing the processes illustrated above.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of manufacturing a semiconductor device, the method comprising:
forming a selection layer and a variable resistance layer on a substrate;
forming a capping layer on the variable resistance layer, the capping layer being formed of an insulating material;
forming a preliminary first mask on the capping layer, the preliminary first mask extending in a first direction;
forming an upper mask on the variable resistance layer and the preliminary first mask such that the preliminary first mask is between the upper mask and the variable resistance layer, the upper mask extending in a second direction crossing the first direction;
etching the preliminary first mask using the upper mask as an etching mask to form a first mask having a pillar shape; and
anisotropically etching the capping layer, the variable resistance layer, and the selection layer using the first mask as an etching mask to form a pattern structure including a variable resistance pattern and selection pattern sequentially stacked, the pattern structure having a pillar shape.

2. The method of claim 1, wherein each of the selection layer and the variable resistance layer includes a chalcogenide-based material.

3. The method of claim 1, wherein the selection layer includes an ovonic threshold switch (OTS) material, and the variable resistance layer includes germanium (Ge), antimony (Sb) and/or tellurium (Te).

4. The method of claim 1, wherein the preliminary first mask includes an insulation material, and includes a metal oxide, a metal nitride or carbon.

5. The method of claim 1, wherein the preliminary first mask is formed to have a thickness of about 20 Å to 100 Å.

6. The method of claim 1, wherein an etch rate of the first mask is less than about 1/10 of an etch rate of each of the variable resistance layer and the selection layer during anisotropically etching the variable resistance layer and the selection layer.

7. The method of claim 1, wherein the preliminary first mask is formed to have a thickness less than about ⅕ of a sum of thicknesses of the variable resistance layer and the selection layer.

8. The method of claim 1, wherein anisotropically etching the variable resistance layer and etching the selection layer are performed under substantially the same process condition.

9. The method of claim 1, wherein the upper mask includes silicon oxide.

10. The method of claim 1, wherein forming the preliminary first mask includes:
forming a first mask layer and a second mask layer on the variable resistance layer;
forming a third mask on the second mask layer, the third mask extending in the first direction;
forming a fourth mask layer on surfaces of the third mask and the second mask layer;
anisotropically etching the fourth mask layer to form a plurality of fourth masks;
removing the third mask between the fourth masks;
etching the second mask layer using the fourth mask as an etching mask to form a second mask; and
etching the first mask layer using the second mask as an etching mask.

11. The method of claim 1, wherein forming the upper mask includes:
forming a first mask layer and a second mask layer on the variable resistance layer and the preliminary first mask;
forming a third mask on the second mask layer, the third mask extending in the second direction;
forming a fourth mask layer on surfaces of the third mask and the second mask layer;
anisotropically etching the fourth mask layer to form a plurality of fourth masks;
removing the third mask between the fourth masks;
etching the second mask layer using the third mask as an etching mask to form a second mask; and
etching the first mask layer using the second mask as an etching mask.

12. A method of manufacturing a semiconductor device, the method comprising:
forming a selection layer and a variable resistance layer on a substrate;
forming a preliminary first mask on the variable resistance layer, the preliminary first mask extending in a first direction;
forming an upper mask on the variable resistance layer and the preliminary first mask, the upper mask extending in a second direction crossing the first direction;
etching the preliminary first mask using the upper mask as an etching mask to form a first mask having a pillar shape; and
anisotropically etching the variable resistance layer and the selection layer using the first mask as an etching mask to form a pattern structure including a variable resistance pattern and selection pattern sequentially stacked, the pattern structure having a pillar shape, wherein forming the pattern structure includes forming a plurality of pattern structures,
and wherein anisotropically etching the variable resistance layer and the selection layer includes forming a recess at an upper portion of the substrate between the plurality of pattern structures.

13. A method of manufacturing a semiconductor device, the method comprising:
forming a plurality of first conductive patterns on a substrate, each of the first conductive patterns extending in a first direction;
forming a selection layer and a variable resistance layer on the first conductive patterns;
forming a capping layer on the variable resistance layer, the capping layer being formed of an insulating material;
forming a preliminary first mask on the capping layer, the preliminary first mask extending in the first direction;
forming an upper mask on the variable resistance layer and the preliminary first mask such that the preliminary first mask is between the upper mask and the variable resistance layer, the upper mask extending in a second direction crossing the first direction;
etching the preliminary first mask using the upper mask as an etching mask to form a first mask having a pillar shape;
anisotropically etching the capping layer, the variable resistance layer, and the selection layer using the first mask as an etching mask to form a pattern structure including a variable resistance pattern and selection pattern sequentially stacked, the pattern structure having a pillar shape; and
forming a plurality of second conductive patterns on the pattern structure, the first second conductive patterns extending in the second direction.

14. The method of claim 13, wherein the selection layer includes an OTS material, and the variable resistance layer includes germanium (Ge), antimony (Sb) and/or tellurium (Te).

15. The method of claim 13, wherein the preliminary first mask includes an insulation material, and includes a metal oxide, a metal nitride or carbon.

16. A method of manufacturing a semiconductor device, the method comprising:
forming a variable resistance layer on a substrate;
forming a selection layer on the variable resistance layer;
forming a capping layer on the selection layer, the capping layer being formed of an insulating material;
forming a preliminary first mask on the capping layer, the preliminary first mask extending in a first direction, the preliminary first mask includes a material having a high etching selectivity with respect to each of the selection layer and the variable resistance layer;
forming an upper mask on the selection layer and the preliminary first mask such that the preliminary first mask is between the upper mask and the selection layer, the upper mask extending in a second direction crossing the first direction;
etching the preliminary first mask using the upper mask as an etching mask to form a first mask having a pillar shape; and
anisotropically etching the capping layer, variable resistance layer, and selection layer using the first mask as an etching mask to form a pattern structure including a selection pattern and a variable resistance pattern sequentially stacked, the pattern structure having a pillar shape.

17. The method of claim 16, wherein the preliminary first mask is formed to have a thickness less than about ⅕ of a sum of thicknesses of the variable resistance layer and the selection layer.

18. The method of claim 16, wherein the preliminary first mask includes an insulation material, and includes a metal oxide, a metal nitride or carbon.

19. The method of claim 16, wherein forming the preliminary first mask includes:
forming a first mask layer and a second mask layer on the selection layer;
forming a third mask on the second mask layer, the third mask extending in the first direction;
forming a fourth mask layer on surfaces of the third mask and the second mask layer;
anisotropically etching the fourth mask layer to form a plurality of fourth masks;
removing the third mask between the fourth masks;
etching the second mask layer using the fourth mask as an etching mask to form a second mask; and
etching the first mask layer using the second mask as an etching mask.

20. The method of claim 16, wherein forming the upper mask includes:
forming a first mask layer and a second mask layer on the selection layer and the preliminary first mask;
forming a third mask on the second mask layer, the third mask extending in the second direction;
forming a fourth mask layer on surfaces of the third mask and the second mask layer;
anisotropically etching the fourth mask layer to form a plurality of fourth masks;
removing the third mask between the fourth masks;
etching the second mask layer using the third mask as an etching mask to form a second mask; and
etching the first mask layer using the second mask as an etching mask.
